(19) United States
(12) Patent Application Publication
(10) Pub. No.: US 2014/0041454 A1
(43) Pub. Date: Feb. 13, 2014

(54) PIEZOELECTRIC RESONATOR, ETCHING AMOUNT DETECTING DEVICE, AND OSCILLATOR

(71) Applicant: Nihon Dempa Kogyo Co., Ltd., Tokyo (JP)

(72) Inventors: MITSUAKI KOYAMA, SAITAMA (JP); TAKERU MUTOH, SAITAMA (JP); MANABU ISHIKAWA, SAITAMA (JP); SHINICHI SATO, SAITAMA (JP)

(73) Assignee: Nihon Dempa Kogyo Co., Ltd., Tokyo (JP)

(21) Appl. No.: 13/964,106

(22) Filed: Aug. 12, 2013

(30) Foreign Application Priority Data
Aug. 13, 2012 (JP) 2012-179417

(51) Int. Cl. G01N 29/12; H03L 1/02; G01R 23/02; H03B 1/04

(52) U.S. Cl. CPC G01N 29/12; H03B 1/04; H03L 1/028; G01R 23/02
USPC 73/579; 310/326; 331/44

(57) ABSTRACT

A piezoelectric resonator includes a plate-shaped crystal element, excitation electrodes, and an unwanted response suppression portion. The excitation electrodes are disposed on both surfaces of the crystal element. The unwanted response suppression portion is formed by inverting a crystallographic axis of the crystal element to suppress an unwanted response that oscillates at a different frequency from a frequency of a main vibration of the crystal element.

### CROSS-REFERENCE TO RELATED APPLICATION

This application claims the priority benefit of Japan application serial no. 2012-179417, filed on Aug. 13, 2012. The entirety of the above-mentioned patent application is hereby incorporated by reference herein and made a part of this specification.

### BACKGROUND OF THE INVENTION

1. Field of the Invention

The present invention relates to a piezoelectric resonator that suppresses occurrence of an unwanted response, and to an etching amount detecting device and an oscillator that use this piezoelectric resonator.

2. Description of the Related Art

A piezoelectric resonator is used in numerous fields such as an electronic device, a measurement device, a communication device, and similar device. However, demand has become significant for downsizing and lower prices from the user in recent years. Increased competition in downsizing is also evident from the fact where crystal units in a 1.6 mm×1.2 mm rectangle are emerging.

On the other hand, further improvements have been requested for frequency stability in the piezoelectric resonator. Especially, an AT-cut crystal unit performs a thickness-shear vibration as a main vibration, and is widely used because of its good frequency characteristic. However, occurrence of unnecessary unwanted response has become a problem. As one cause of the unwanted response, for example, in the case where the thickness-shear vibration is assumed to be the main vibration, the unwanted responses by profile-shear vibration, flexure vibration, or similar are possible. The unwanted responses cause the occurrence of what is called Frequency dips and Activity dips. Frequency dips and Activity dips are a rapid change of resonance frequency, motional resistance, or similar parameter that occurs when the temperature of the crystal unit is continuously changed.

A portion that causes the unwanted response is determined by the design specification. Conventionally, when the crystal unit is large, attachment of an adhesive to the portion that causes the unwanted response or similar measure has been performed. However, as the crystal unit becomes downsized, a motional resistance is changed by a weight of the adhesive. This has been apparent as a problem. Additionally, it is difficult to attach the adhesive to the downsized crystal unit as a process.

Other countermeasures for the unwanted response include methods of: selecting appropriate dimensions of a piezoelectric piece corresponding to the usage; changing a shape of a piezoelectric piece (bevel machining, convex machining, or similar machining); changing a structure of a piezoelectric piece into a mesa structure by a MEMS technique; and similar method. Currently, it is required to take a measure for downsizing, stabilizing a frequency, and mass production of the piezoelectric resonator. A need exists for a technique that ensures compatibility with downsizing and frequency stability at low cost.

Japanese Unexamined Patent Application No. Sho 60-58709 discloses a configuration where a depressed portion is disposed on a principal surface of a piezoelectric piece in FIGS. 4A and 4B. Japanese Unexamined Patent Application No. Hei 1-265712 discloses a configuration where a hole is disposed in an electrode tab portion and a pocket is disposed in a crystal blank in FIG. 1 and FIG. 3. Further, Japanese Unexamined Patent Application No. 2001-257560 discloses a structure where an opening portion is formed in an excitation electrode in Paragraph 0007 and FIG. 1. Japanese Unexamined Patent Application No. Hei 6-338755 discloses a configuration where a depressed portion is formed to suppress an unwanted response in a crystal element in Paragraphs 0012 and 0014. However, even use of these techniques cannot shift an oscillation frequency of the unwanted response to the range that does not affect the main vibration. Therefore, the problem of the present invention cannot be solved.

### CITATION LIST

### [Patent Literatures]

[Patent Literature 1] Japanese Unexamined Patent Application No. Sho 60-58709, FIGS. 4A and 4B
[Patent Literature 2] Japanese Unexamined Patent Application No. Hei 1-265712, FIG. 1 and FIG. 3
[Patent Literature 3] Japanese Unexamined Patent Application No. 2001-257560, Paragraph [0007] and FIG. 1
[Patent Literature 4] Japanese Unexamined Patent Application No. Hei-6-338755, Paragraphs [0012] and [0014]

The present invention has been made in view of the above-described circumstances, and it is an object of the present invention to provide a technique that suppresses occurrence of an unwanted response in a piezoelectric resonator.

### SUMMARY

A piezoelectric resonator of the present invention includes a plate-shaped crystal element, excitation electrodes, and an unwanted response suppression portion. The excitation electrodes are disposed on both surfaces of the crystal element. The unwanted response suppression portion is formed by inverting a crystallographic axis of the crystal element to suppress an unwanted response that oscillates at a different frequency from a frequency of a main vibration of the crystal element.

In this piezoelectric resonator, a plurality of the unwanted response suppression portions may be disposed symmetrically to the center of the excitation electrode.

Additionally, the unwanted response suppression portion may be disposed at one of a position directly below the excitation electrode and a position directly below an extraction electrode connected to the excitation electrode.

The crystal element may include a first region where the crystallographic axis is not inverted and a second region where the crystallographic axis is inverted. The first region may include the excitation electrodes and the unwanted response suppression portion. The second region may include other excitation electrodes different from the excitation electrodes. The other excitation electrodes may be disposed on both surfaces of the crystal element.

The piezoelectric resonator of the present invention selects the position where the large unwanted response is generated by the excitation electrode on the piezoelectric plate and forms the unwanted response suppression portion on the surface of this position, so as to shift the oscillation frequency to a low frequency side in the unwanted response suppression portion. This reduces the negative effect due to the unwanted response in the piezoelectric resonator to obtain a piezoelectric resonator with a stable frequency characteristic.

### BRIEF DESCRIPTION OF THE DRAWINGS

FIG. 1 is a plan view and a cross-sectional view each illustrating an exemplary crystal unit according to a first embodiment of the present invention;

FIGS. 2A to 2F are process drawings illustrating an exemplary method for manufacturing the crystal unit;

FIG. 3 is a plan view and a cross-sectional view each illustrating a modification of the crystal unit according to the first embodiment of the present invention;

FIGS. 4A and 4B are explanatory drawings each illustrating an occurrence region of an unwanted response in the crystal unit;

FIG. 5 is a plan view and a cross-sectional view each illustrating an exemplary crystal unit according to a second embodiment of the present invention;

FIGS. 6A to 6G are process drawings illustrating an exemplary method for manufacturing the crystal unit;

FIG. 7 is a vertical cross-sectional view illustrating an exemplary etching amount sensor including the crystal unit according to the first embodiment of the present invention;

FIG. 8 is a circuit diagram of an exemplary circuit that employs a crystal unit according to the second embodiment of the present invention;

FIGS. 9A and 9B are graphs each representing a relationship between frequency and admittance in a piezoelectric resonator;

FIG. 10 is a graph representing a correlation between frequency and temperature regarding the main vibration and the unwanted response in the piezoelectric resonator;

FIG. 11 is a circuit diagram illustrating an exemplary circuit that employs the piezoelectric resonator of the present invention;

FIGS. 12A and 12B are graphs representing respective temperature characteristics of frequencies in a working example and a comparative example; and

FIG. 13 is a plan view and a cross-sectional view each illustrating an exemplary conventional crystal unit.

### DETAILED DESCRIPTION

### First Embodiment

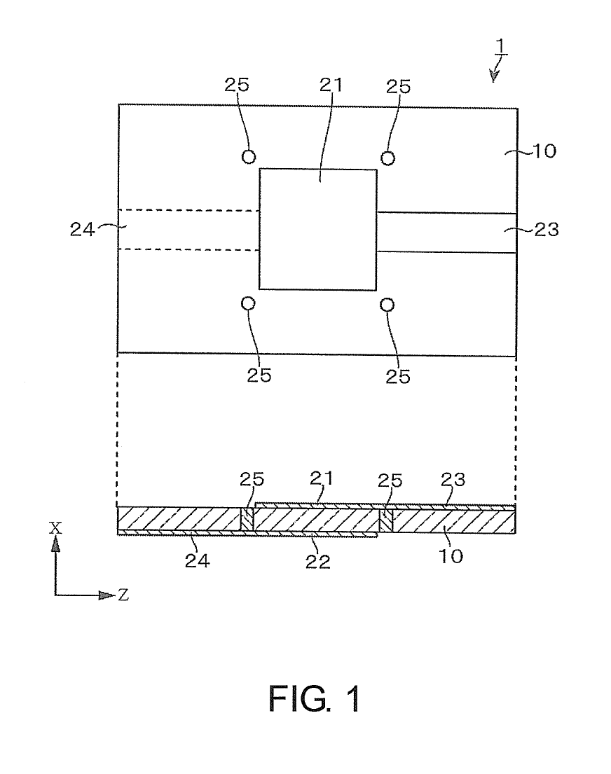

Hereinafter, a description will be given of one embodiment of a crystal unit that forms a piezoelectric resonator of the present invention. As illustrated in FIG. 1, a crystal unit 1 includes respective excitation electrodes 21 and 22 on both surfaces of a crystal element 10 that forms a piezoelectric body. For example, the crystal element 10 employs a fundamental wave mode AT-cut crystal element and oscillates in a thickness-shear vibration mode as a main vibration at 38.4 MHz. As one example of this embodiment, the crystal element 10 is formed in, for example, a rectangular shape that has a rectangular planar shape. The dimensions are set to 1.0 mm length×0.8 mm width, and the thickness is set to 43.2 μm.

The excitation electrodes 21 and 22 are formed to face one another at the center of both surfaces of the crystal element 10 to excite the crystal element 10. These excitation electrodes 21 and 22 have, for example, square shapes, and are arbitrarily set corresponding to the usage. For example, one side is set to 0.6 mm. Further, an extraction electrode 23 is connected to the center of one end of the excitation electrode 21 at one surface side of the crystal element 10. The extraction electrode 23 is extracted toward the peripheral edge of the crystal element 10. An extraction electrode 24 is connected to one end of the excitation electrode 22 at the other surface side of the crystal element 10. The extraction electrode 24 is extracted toward the peripheral edge in the opposite direction of the extraction electrode 23. The directions to extract the extraction electrodes 23 and 24 extend along the Z-axis direction of the crystal element 10 as illustrated in FIG. 1. The excitation electrode 21 and the extraction electrode 23 are integrally formed, and the excitation electrode 22 and the extraction electrode 24 are integrally formed. These electrodes are formed of laminated films made of chrome (Cr), gold (Au), and similar material.

The shapes of the excitation electrodes 21 and 22 are set as needed. The excitation electrodes 21 and 22 may be formed to the proximity of the outer edge of the crystal element 10.

Further, the crystal element 10 includes unwanted response suppression portions 25, for example, in four positions. In the unwanted response suppression portion 25, the crystal axis of the crystal element 10 is inverted by heat treatment described later. In describing FIG. 1 as an example, the unwanted response suppression portions 25 are equally spaced from the center of the excitation electrode 21 on the extended line of the diagonal line of the excitation electrode 21 at the outer side of respective corner portions.

The unwanted response suppression portions 25 are formed to suppress the occurrence of a different frequency from an oscillation frequency of main vibration, in this example, occurrence of the unwanted response by profile-shear vibration and flexure vibration. Accordingly, these unwanted response suppression portions 25 are each formed in a predetermined size at a position to suppress the unwanted response in the excitation electrode 21. Here, the unwanted response suppression includes a case where gain of the unwanted response is attenuated, in addition to a case where the occurrence of the unwanted response is completely prevented.

The size of the unwanted response suppression portion 25 is equivalent almost to a dot. As one example of the dimensions, in the case where the unwanted response suppression portion 25 is formed inside the crystal element 10, the radius is 25 μm for example. In the respective drawings, the actual size of the unwanted response suppression portion 25 is ignored and the unwanted response suppression portion 25 is illustrated in a large size for ease of recognition.

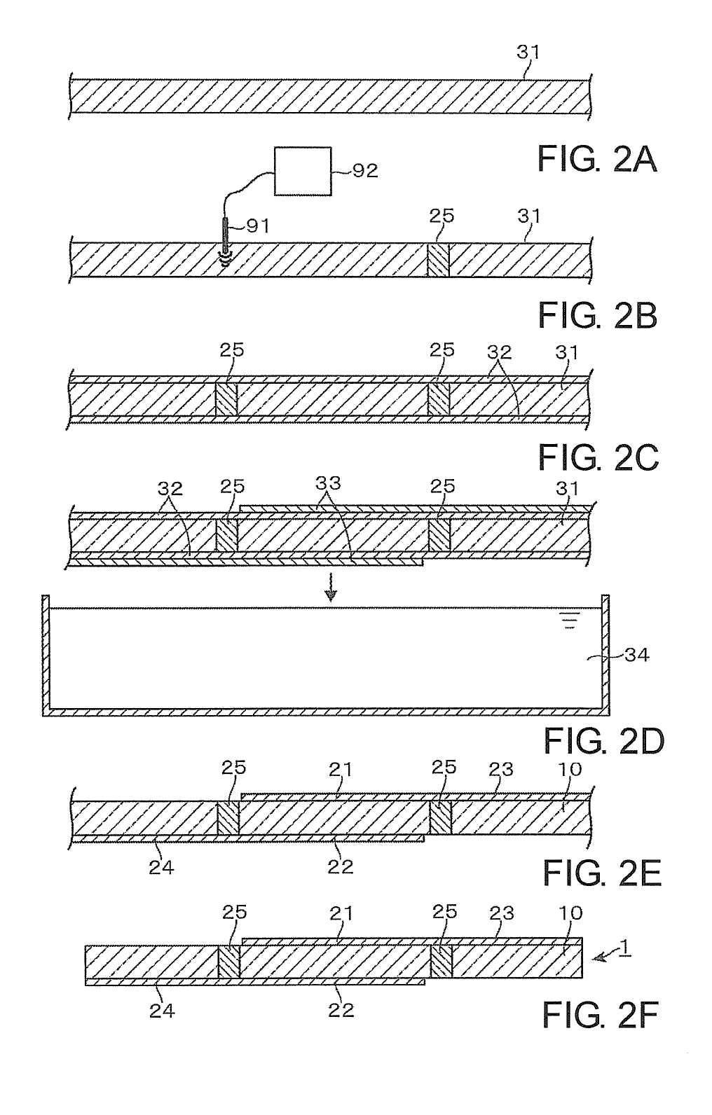

Next, a method for producing the crystal unit 1 will be described with reference to FIGS. 2A to 2F.

FIGS. 2A to 2F describe an exemplary method for producing the crystal unit 1 to be produced in a part of one crystal substrate. First, one cut crystal substrate 31 is polished and cleaned (see FIG. 2A). On the crystal substrate 31, the unwanted response suppression portion 25 is formed by inverting the crystal axis to have a dot shape. Known methods for forming an axis inverting portion of the crystal include a method by heat, a method by a combination of pressure and heat, and similar method. However, in this embodiment, the unwanted response suppression portion 25 is formed by heat.

As a method for forming the unwanted response suppression portion 25 in this embodiment, a microscopic probe 91 connected to a heat source 92 is pierced at a predetermined position on the crystal substrate 31, and heat energy is supplied from the heat source 92 to heat the tip of the probe 91. The temperature of the tip reaches a temperature to the extent that a pierced portion by the probe 91 in the crystal substrate 31 is inverted in a dot shape, for example, 600° C. For example, the dot-shaped unwanted response suppression portion 25 with a diameter of 50 μm is formed by heating (see FIG. 2B). This heating process inverts a direction of the X-axis that is a crystallographic axis of the AT-cut crystal element.

On completion of the formation of the unwanted response suppression portion 25, electrode films (metal films) 32 are formed on both surfaces of the crystal substrate 31 by evaporation or sputtering (see FIG. 2C). In the metal film 32, for example, an Au layer is laminated on a Cr layer. Subsequently, resist liquid is applied over the metal film 32 by a resist liquid applying mechanism (not shown) corresponding to desired shapes of the excitation electrodes 21 and 22 and desired shapes of the extraction electrodes 23 and 24. Then, the resist liquid is solidified so as to form a resist film 33 (see FIG. 2D).

After these processes, the crystal substrate 31 is immersed in a KI (potassium iodide) solution 34, and a portion where the metal film 32 is exposed is etched by wet etching. Thus, the crystal substrate 31 is obtained (see FIG. 2E). The crystal substrate 31 includes the unwanted response suppression portion 25, the excitation electrodes 21 and 22, and the extraction electrodes 23 and 24. Subsequently, the crystal unit 1 is produced by cutting off the crystal substrate 31 to have one combination of these electrodes, the unwanted response suppression portion 25, and similar member (see FIG. 2F).

With the crystal unit 1 of this embodiment, the unwanted response suppression portion 25 is disposed at the position where the unwanted response becomes largest at the one surface side of the excitation electrode 21. This attenuates the gain of the unwanted response oscillating in this region. The unwanted response suppression portion 25 has an elastic constant different from that of a portion where the axis is not inverted. Thus, the unwanted response suppression portion 25 is found to have an oscillation frequency lower by around 63% compared with the oscillation frequency of the main vibration. Accordingly, the oscillation frequency of the unwanted response is shifted to a low frequency side. On the other hand, the oscillation frequency of the main vibration does not change. This increases a frequency difference between the oscillation frequency of the main vibration and the oscillation frequency of the unwanted response. Further, the unwanted response of the unwanted response suppression portion 25 is not elastically coupled to the main vibration. This suppresses a negative effect generated by the unwanted responses, for example, Frequency dips and Activity dips.

### Modification of the First Embodiment

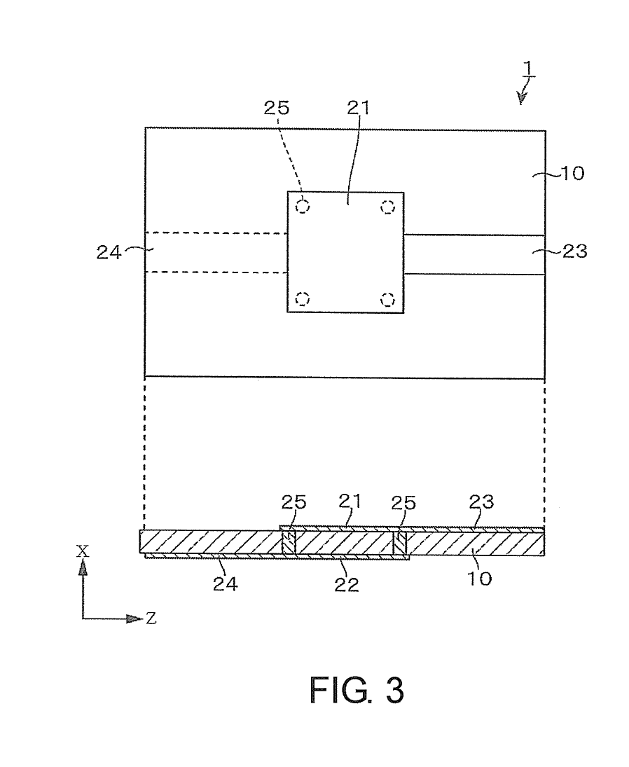

Subsequently, another example of the crystal unit 1 will be described with reference to FIG. 3. As illustrated in FIG. 3, in the crystal unit 1, the unwanted response suppression portion 25 exists within a range of the excitation electrode 21. That is, the unwanted response suppression portion 25 has a form covered by the excitation electrode 21.

While in this modification the unwanted response suppression portion 25 is formed directly below the excitation electrode 21, any position is possible insofar as the position allows suppressing the unwanted response. The unwanted response suppression portion 25 may be formed directly below the extraction electrode 23. Also in the modification, the crystal unit 1 can be produced by the above-described method illustrated in FIGS. 2A to 2F.

Similarly to the first embodiment, this modification also attenuates the gain due to the unwanted response. Additionally, shifting the oscillation frequency of the unwanted response to a low frequency side allows suppressing the negative effect generated by the unwanted responses, for example, Frequency dips and Activity dips. Further, this modification suppresses the unwanted response directly below the excitation electrode 21, thus effectively reducing the negative effect of the unwanted response directly on the excitation electrode 21.

Here, a description will be given of a method for specifying a region where the unwanted response occurs, using an actual crystal unit. A first method is a method for measuring an X-ray diffraction strength. First, a frequency causing the unwanted response is examined, and then an A.C. voltage of this frequency is applied to the crystal unit. In a state where the voltage is applied, X-ray is irradiated to the crystal unit from a predetermined angle with respect to the normal direction. For example, in a state where this angle is maintained with respect to the crystal unit, the irradiation position of the X-ray is changed so as to scan the entire surface of the crystal unit with the X-ray. The X-ray diffraction strength is measured for each irradiation position to make a map of the diffraction strength on the surface of the crystal unit.

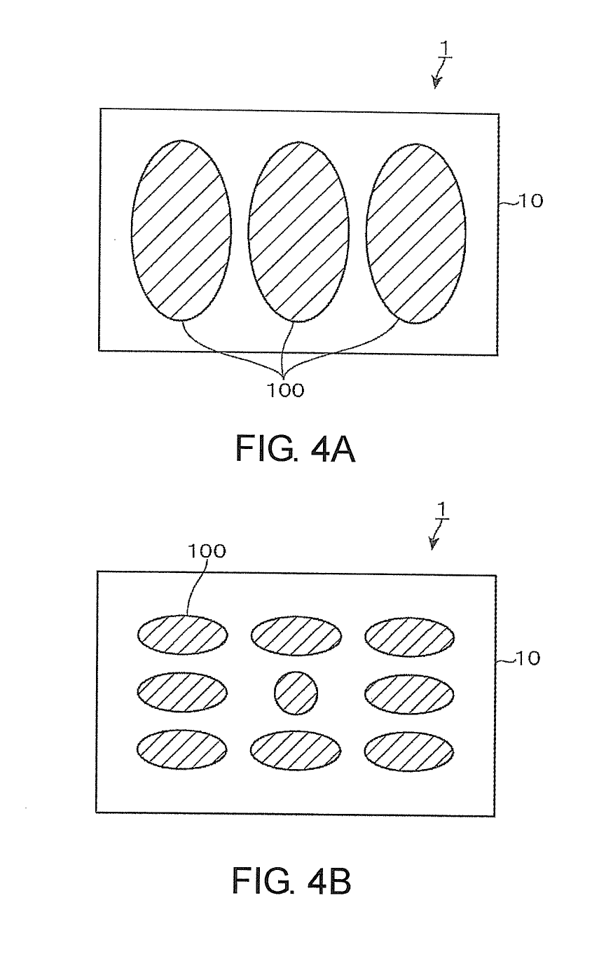

FIGS. 4A and 4B are exemplary maps of the X-ray diffraction strength. The unwanted response occurs in a region 100 illustrated by the diagonal lines.

A second method is a method referred to as a probe method. Specifically, first, an A.C. voltage at a frequency that causes the unwanted response is applied between the excitation electrodes of the crystal unit. In this state, a grounded probe is brought into contact with the surface of the crystal element (brought into contact with the surface of the crystal element in a state where the probe passes through the excitation electrode in a portion where the excitation electrode exists) to measure a voltage between the probe and the earth with a voltmeter. With this measurement, a charge distribution in each portion on the surface of the crystal element is obtained. This allows making a similar map to that made by the first method.

Further, a third method is a method using laser light. Specifically, the crystal element is placed on a XY table. A laser light is irradiated to the crystal element by spot irradiation. An oscillation frequency of the crystal element is measured at the irradiation position. Subsequently, a laser light is scanned over the entire surface of the crystal element, and an oscillation frequency is measured for each spot position. In this measurement, the oscillation frequency is measured for each portion on the surface of the crystal element. This allows making a similar map to the map made by the first method.

Thus, an oscillation region of the unwanted response is obtained, and the above-described unwanted response suppression portion 25 is formed in the oscillation region.

As illustrated in FIGS. 4A and 4B, unwanted response regions are often symmetrical to each other with respect to the center of the crystal element 10. Therefore, it is preferred that the unwanted response suppression portions 25 be formed symmetrically to the center of the crystal element 10. Also in the first embodiment and the modification, as illustrated in FIG. 1 and FIG. 3, the unwanted response suppression portions 25 are positioned symmetrically to the center of the crystal element 10.

Accordingly, disposing the unwanted response suppression portions 25 symmetrically to the center of the crystal element 10 provides an even balance between right and left portions. This allows stabilizing the frequency of the main vibration in the long term compared with a state where the right and left portions are not balanced.

In this embodiment, a description will be given of a reason for employing twinning of the crystal by heat as a method for producing the unwanted response suppression portion 25.

A crystal at ordinary temperature has a structure referred to as an α-quartz structure with piezoelectricity in the trigonal crystal system. However, when the crystal is heated to 573° C., a phenomenon referred to as phase transition occurs. Then, the structure changes into a structure referred to as a β-quartz structure without piezoelectricity in the hexagonal crystal system. This phase transition is a reversible phenomenon. However, after the crystal is changed to have the β-quartz structure by heating, re-transition from the β-quartz structure to the α-quartz structure does not occur uniformly even in the case where the crystal is cooled. A part of the crystal remains in the β-quartz structure. Therefore, twinning occurs in this portion. Accordingly, piezoelectricity is reduced in the twinned portion compared with a non-twinned portion. In the case where the crystal element is used as a piezoelectric resonator, this twinned portion suppresses vibration at the oscillation frequency.

With this effect, in this embodiment, twinning of the crystal element 10 in the unwanted response portion is selected as a method for forming the unwanted response suppression portion 25.

Here, regarding the crystal unit 1 of this embodiment, the unwanted response suppression portion 25 is formed before forming the electrodes 21 to 24. However, concentration of heat and pressure allows forming the unwanted response suppression portion 25 even after the electrodes are formed.

### Second Embodiment

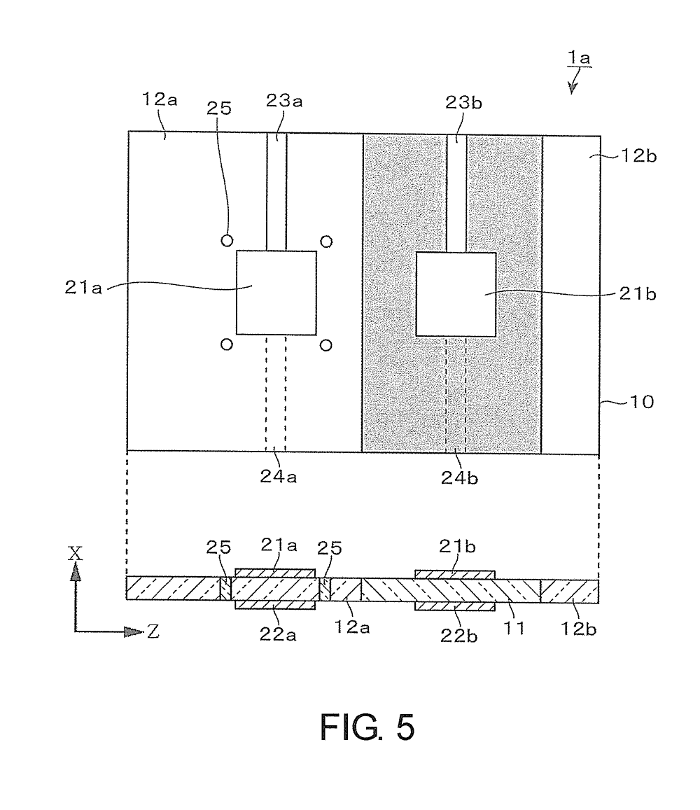

Hereinafter, a description will be given of another embodiment of a crystal unit that forms a piezoelectric resonator of the present invention with reference to FIG. 5. A crystal unit 1a of this embodiment will be described with reference to a crystal unit 1a illustrated FIG. 5 as an example. For example, the crystal element 10 used in the crystal unit 1a employs a fundamental wave mode AT-cut crystal element and oscillates in a thickness-shear vibration mode as a main vibration at 38.4 MHz. As one example of this embodiment, the crystal element 10 is formed in, for example, a rectangular shape that has a rectangular planar shape. The dimensions are set to 1.0 mm length×1.6 mm width, and the thickness is set to 43.2 μm.

In this embodiment, a part in a strip shape of the crystal element 10 is twinned by axis inversion. In the crystal unit 1a, a strip-shaped portion where the axis is inverted is referred to as an axis inversion portion 11 and a portion where the axis is not inverted (that is, an axis non-inversion portion) is referred to as an AT-cut portion 12. In the crystal element 10, for example, the axis inversion portion 11 is formed at the right side of the crystal element 10 with respect to the center axis in the Z-axis direction and formed along the X-axis direction. However, the axis inversion portion 11 is formed such that an AT-cut portion 12b has a certain width at the right edge of the crystal element 10 and exists along the X-axis direction so as not to have the axis inversion portion 11 over the entire right half of the crystal element 10. On the other hand, an AT-cut portion 12a without the axis inversion is formed at the left side of the crystal element 10 with respect to the center axis.

For ease of distinguishing between the axis inversion portion 11 and the AT-cut portion 12, the axis inversion portion 11 is hatched in FIG. 5.

Respective excitation electrodes are formed in the axis inversion portion 11 and the AT-cut portion 12a on the left side of the crystal element 10. Excitation electrodes 21a and 22a are formed on both surfaces of the crystal element 10 in the AT-cut portion 12a. Excitation electrodes 21b and 22b are formed on both surfaces of the crystal element 10 in the axis inversion portion 11. Both the excitation electrodes 21a and 22a and the excitation electrodes 21b and 22b have square shapes for example. Each square shape has one side of, for example, 0.6 mm that is set as needed corresponding to the usage. While in the example of FIG. 5 a combination of the excitation electrodes 21a and 22a and a combination of the excitation electrodes 21b and 22b have the same shape in the same size, each combination may have a different size.

From the excitation electrode 21a, an extraction electrode 23a is connected in a direction without overlapping the axis inversion portion 11, for example, along the X-axis direction of the crystal unit 1. From the excitation electrode 22a, an extraction electrode 24a is connected. The extraction electrode 24a is extracted toward the peripheral edge in the opposite direction of the extraction electrode 23a.

On the other hand, from the excitation electrode 21b, an extraction electrode 23b is connected in a direction without overlapping the AT-cut portions 12a and 12b, for example, along the X-axis direction of the crystal unit 1. From the excitation electrode 22b, an extraction electrode 24b is connected. The extraction electrode 24b is extracted toward the peripheral edge in the opposite direction of the extraction electrode 23b.

The AT-cut portion 12a includes the unwanted response suppression portions 25, for example, in four positions. In the unwanted response suppression portion 25, the crystal axis of the AT-cut portion 12a is inverted by the above-described heat treatment for example. In the crystal unit 1a of FIG. 5, the unwanted response suppression portions 25 are equally spaced from the center of the excitation electrode 21a on the extended line of the diagonal line of the excitation electrode 21a, and are disposed at the outer side of respective corner portions. These unwanted response suppression portions 25 correspond to the unwanted response suppression portion in the AT-cut portion 12a.

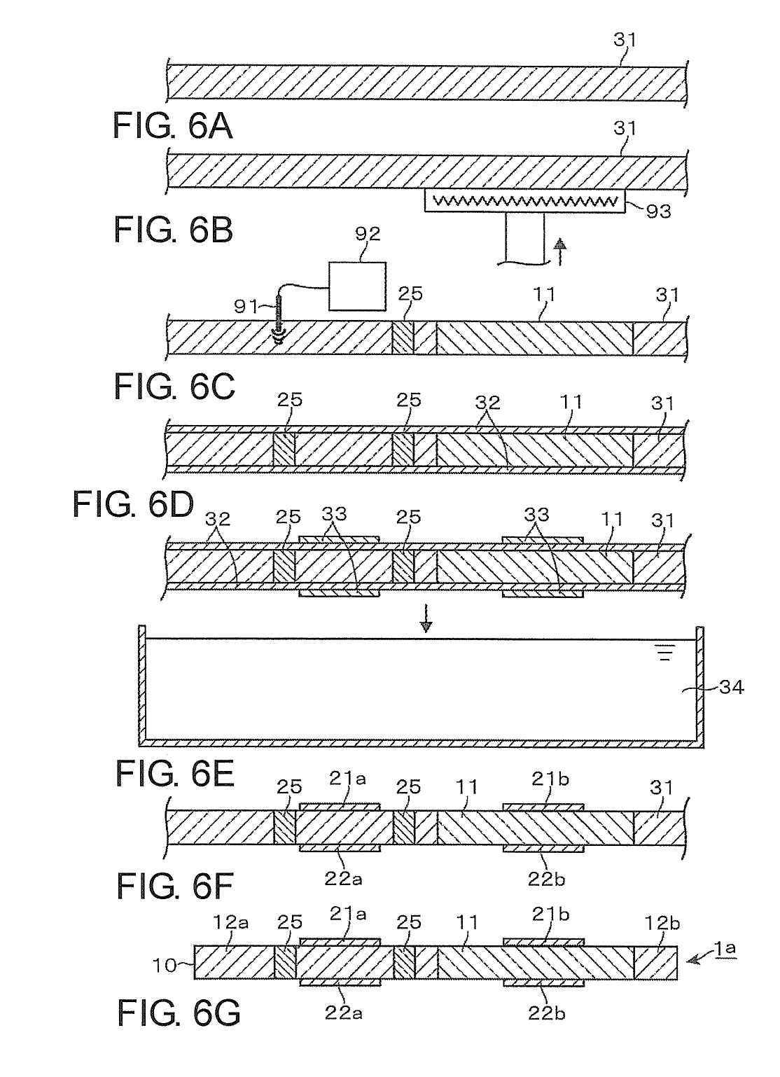

Subsequently, a method for producing the crystal unit 1a will be simply described with reference to FIGS. 6A to 6G.

First, the axis inversion portion 11 is formed on the crystal substrate 31 that is polished and cleaned (see FIG. 6A). As a forming method, a portion desired to invert the axis is heated to 600° C., for example, with a strip-shaped heater 93 (see FIG. 6B). The heating method is not limited to a method using a heater. The heating method may be a method using a laser light, an infrared light, or similar light, or may be a method using a combination of pressure and heat. Subsequently, on the crystal substrate 31 where the axis inversion portion 11 is formed, the probe 91 is pierced to a desired portion of the AT-cut portion 12. The probe 91 is connected to the heat source 92 for example, similarly to the first embodiment. Then, the crystal substrate 31 is heated to form the unwanted response suppression portion 25 (see FIG. 6C).

After the axis inversion portion 11 and the unwanted response suppression portion 25 are formed, the metal films 32 are formed on both surfaces of the crystal substrate 31 similarly to the first embodiment (see FIG. 6D). On the metal films 32, the respective resist films 33 are formed corresponding to the desired shapes of the excitation electrodes 21a, 21b, 22a, and 22b and the extraction electrodes 23a, 23b, 24a, and 24b (see FIG. 6E). This crystal substrate 31 is etched by, for example, wet etching to form these excitation electrodes (see FIG. 6F). Finally, the crystal unit 1a is obtained by cutting off the crystal substrate 31 to have one combination of these electrodes and the unwanted response suppression portion 25 (see FIG. 6G).

With the crystal unit 1a of this embodiment, the oscillation frequency of the axis inversion portion 11 is found to have a frequency around 63% of the oscillation frequency of the AT-cut portion 12 because of different elastic constants. Accordingly, the oscillation frequency in the axis inversion portion 11 completely differs from the oscillation frequency of the AT-cut portion 12, and the two vibrations are not elastically coupled together. This allows using the following respective resonators in different applications. One resonator is centered on the excitation electrodes 21a and 22a on the AT-cut portion 12a. The other resonator is centered on the excitation electrodes 21b and 22b on the axis inversion portion 11. That is, this ensures a plurality of crystal unit portions on one crystal element.

Here, while in this embodiment the axis inversion portion 11 has a strip shape, the axis inversion portion 11 may have another shape. For example, the axis inversion portion 11 may be formed in a square shape on the crystal element 10.

Around the excitation electrode 21a on the AT-cut portion 12, the plurality of unwanted response suppression portions 25 is formed at the selected positions where the unwanted response becomes large. Therefore, the unwanted response is shifted to a low frequency side in the unwanted response suppression portion 25 on the AT-cut portion 12a. Accordingly, similarly to the crystal unit 1 of the first embodiment, a frequency difference is increased between the oscillation frequency of the main vibration and the oscillation frequency of the unwanted response. This allows suppressing the negative effect generated by the unwanted responses, for example, Frequency dips and Activity dips. Further, the modification described in the first embodiment is applicable to the second embodiment.

As described above, the plurality of excitation electrodes can be formed on one crystal element. This allows integration of components in a product that includes a large number of crystal units. Thus, downsizing, cost-cutting, and similar effect are expected.

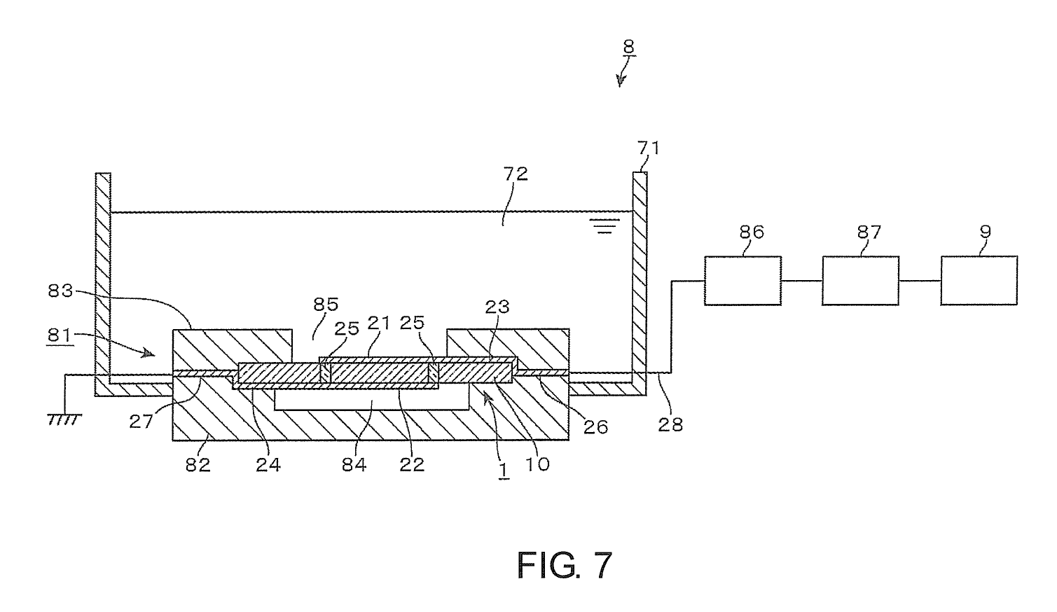

Next, a description will be given of a case using the crystal unit 1 for an etching amount sensor with reference to FIG. 7 as an application example of the crystal unit 1 of the first embodiment. This etching amount sensor 8 houses the crystal unit 1, which forms a piezoelectric resonator, in a container 81. The configuration of the crystal unit 1 is similar to that illustrated in the above-described FIG. 3. The unwanted response as a suppressing target provides an oscillation at a higher frequency than that of the main vibration. The container 81 includes, for example, a base body 82 and a lid body 83. A depressed portion 84 is formed in approximately the center of the base body 82. The crystal unit 1 is held in the container 81 such that the excitation electrode 22 on the other surface side of the crystal unit 1 faces an airtight space formed by the depressed portion 84.

On the other hand, the lid body 83 is disposed to cover the crystal unit 1 placed on the base body 82 from the upper side. The lid body 83 is airtightly connected to the base body 82 at the outer side of a region where the crystal unit 1 is disposed. The lid body 83 includes an opening portion 85 formed such that only the excitation electrode 21 at the one surface side of the crystal unit 1 and a part of the crystal element 10 at the one surface side are brought into contact with the etchant. That is, the opening portion 85 is formed surrounding a region that is approximately 5 mm outside of the excitation electrode 21 so as to form an etching region around the excitation electrode 21. Additionally, the lid body 83 is made of material with a lower etching speed than that of the crystal element 10 with respect to the etchant, for example, polytetrafluoroethylene to have contact with the etchant.

Further, the container 81 includes wiring electrodes 26 and 27 connected to the respective extraction electrodes 23 and 24, for example, between the base body 82 and the lid body 83. The extraction electrode 23 electrically connects to the wiring electrode 26 while the extraction electrode 24 electrically connects to the wiring electrode 27. For example, the wiring electrode 26 at one side connects to an oscillation circuit 86 through a signal line 28 while the wiring electrode 27 at the other side is grounded. The latter part of the oscillation circuit 86 connects to a controller 9 through a frequency measuring unit 87. The frequency measuring unit 87 plays a role in, for example, performing digital processing of a frequency signal as an input signal and measuring the oscillation frequency of the crystal unit 1.

In the controller 9, a memory preliminarily stores obtained data that associates variation in oscillation frequency with etching amount. The controller 9 performs: a function for obtaining a set value of the variation in oscillation frequency corresponding to a target value of the etching amount input by the operator; a function for obtaining a variation in oscillation frequency of the crystal unit 1 at the time of measurement; and a function for outputting a predetermined control signal when the variation in oscillation frequency becomes the set value. Additionally, the controller 9 performs a function for displaying a corresponding etching amount on a display screen, for example, when the variation in oscillation frequency obtained at the time of measurement becomes a predetermined value.

The etching amount sensor 8 connects to an etching container 71 such that only the one surface side of the container 81 has a contact with the etchant 72. Therefore, only the excitation electrode 21 at the one surface side of the crystal unit 1 and a part of the one surface side of the crystal element 10 are brought into contact with an etchant 72 in the etching container 71. In the etching container 71, a process target body is not illustrated. In practice, a process target body as an etching target such as a crystal element is disposed at a predetermined position in the etching container 71. This predetermined position is a position where a process target surface of the process target body and the crystal element 10 at the one surface side of the etching amount sensor 8 are brought into contact with the etchant 72 at the same timing.

Next, a description will be given of an operation of the etching amount sensor 8 of the present invention. First, the process target body is carried in the etching container 71, and the etching amount sensor 8 is mounted at the etching container 71 as described above. Subsequently, the predetermined etchant 72 is supplied into the etching container 71. Here, the operator inputs a target value of the etching amount on the display screen of the controller 9. Thus, the process target body is brought into contact with the etchant 72 to progress the etching of the process target surface. On the other hand, in the etching amount sensor 8, only the excitation electrode 21 at the one surface side of the crystal unit 1 and a part of the one surface side of the crystal element 10 are brought into contact with the etchant 72. Etching is performed on a region in contact with the etchant 72 at the one surface side of the crystal element 10. Thus, the outside dimension of the crystal element 10 is decreased as the etching is progressed. This shifts the oscillation frequency of the main vibration to a high frequency side.

At this time, the etching amount sensor 8 measures a frequency as the frequency signal of the crystal unit 1. This measured frequency is stored in the memory. For example, in the case where the variation in oscillation frequency obtained at the time of measurement becomes the set value, the control signal is output and the process target body is carried out of the inside of the etchant 72, for example, by a tool (not shown). Subsequently, the etching process is terminated. That is, since the variation in oscillation frequency of the etching amount sensor 8 corresponds to the etching amount of the crystal unit 1, this variation is equivalent to an estimated value of the etching amount of the process target body. In this example, the etching amount sensor 8 and the frequency measuring unit constitute the etching amount detecting device.

With the embodiments, the unwanted response suppression portion 25 is formed in the crystal unit 1. This shifts the oscillation frequency of the unwanted response to a low frequency side and reduces the gain of the unwanted response. Therefore, even in the case where the etching of the crystal element 10 proceeds and the oscillation frequency of the main vibration is shifted to a high frequency side, the oscillation frequency of the main vibration and the oscillation frequency of the unwanted response do not overlap each other. This prevents frequency jump, thus ensuring a large measurement range.

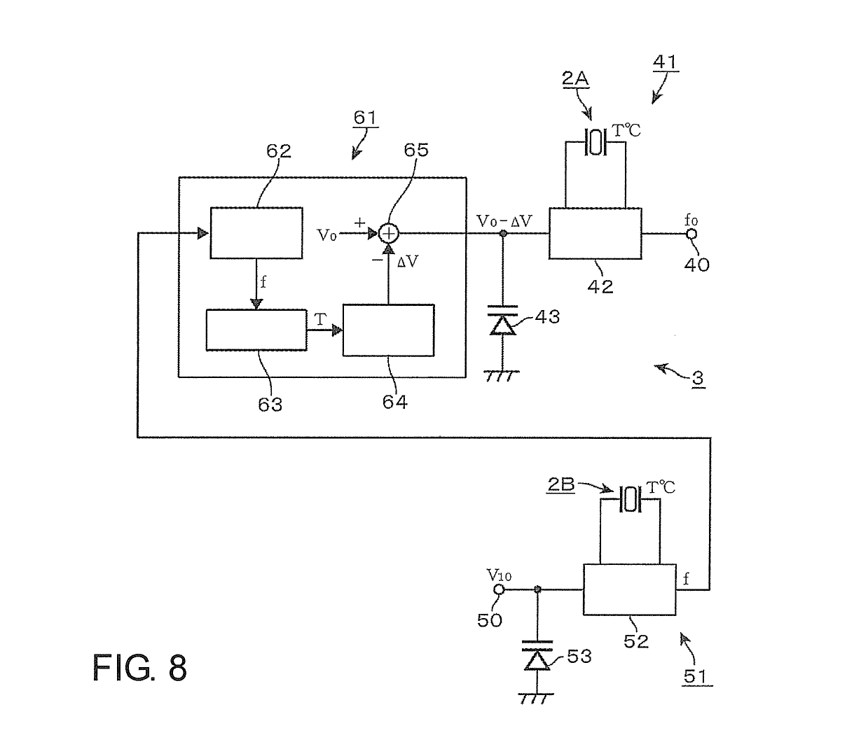

Further, for example, the crystal unit 1a of the second embodiment can be used as a temperature compensated crystal oscillator (TCXO) as illustrated in FIG. 8. FIG. 8 will be simply described as follows. The crystal unit portion including the AT-cut portion 12 is assumed to be a crystal unit 2A. The crystal unit portion including the axis inversion portion 11 is assumed to be a crystal unit 2B. The crystal unit 1a includes two oscillation regions that vibrate independently. Therefore, the crystal unit 1a is considered to include the two crystal units 2A and 2B for convenience as illustrated in FIG. 8.

A TCXO 3 includes a main oscillator 41, an auxiliary oscillator 51, and a control voltage supplying unit 61. The main oscillator 41 is used for outputting a signal of a set frequency f₀ to the outside. The auxiliary oscillator 51 is used for oscillating a temperature compensating signal. The control voltage supplying unit 61 is disposed between the main oscillator 41 and the auxiliary oscillator 51 to calculate a control voltage V_{c} received at the main oscillator 41 based on the temperature compensating signal. The temperature compensating signal is output from the auxiliary oscillator 51. A terminal 50 in FIG. 8 is an input terminal of a control voltage V₁₀ of the auxiliary oscillator 51. A terminal 40 is an output terminal of the TCXO 3.

The main oscillator 41 includes the crystal unit 2A and a main oscillation circuit 42 connected to the crystal unit 2A. The auxiliary oscillator 51 includes the crystal unit 2B and an auxiliary oscillation circuit 52 connected to the crystal unit 2B. The former part (the input side) of the main oscillator 41 connects to the control voltage supplying unit 61. The control voltage V_{c} is applied to the main oscillator 41 from the control voltage supplying unit 61 via a varicap diode 43. The control voltage supplying unit 61 subtracts a temperature compensation voltage ΔV from a reference voltage V₀ of the main oscillator 41 so as to generate the control voltage V_{c}.

A frequency detecting unit 62 detects an oscillation frequency of an auxiliary oscillation circuit. A temperature estimating unit 63 estimates a temperature of an atmosphere where the crystal units 2A and 2B are placed, based on the frequency detected by the frequency detecting unit. A compensation voltage operating unit 64 performs an operation of a temperature compensation voltage to be added to a set voltage of a control voltage, based on the temperature estimated by the temperature estimating unit 63. An adder 65 adds the set voltage and the temperature compensation voltage.

Heating an AT-cut crystal inverts a direction of the X-axis. The crystal where the direction of the X-axis is inverted has approximately a linear function relationship between a frequency and a temperature. Accordingly, detection of the oscillation frequency of the crystal unit 2B allows detecting a temperature of the atmosphere with high accuracy. This allows appropriate temperature compensation for the oscillation frequency of the crystal unit 2A.

Here, the relationship between the main vibration and the unwanted response in the piezoelectric resonator will be examined.

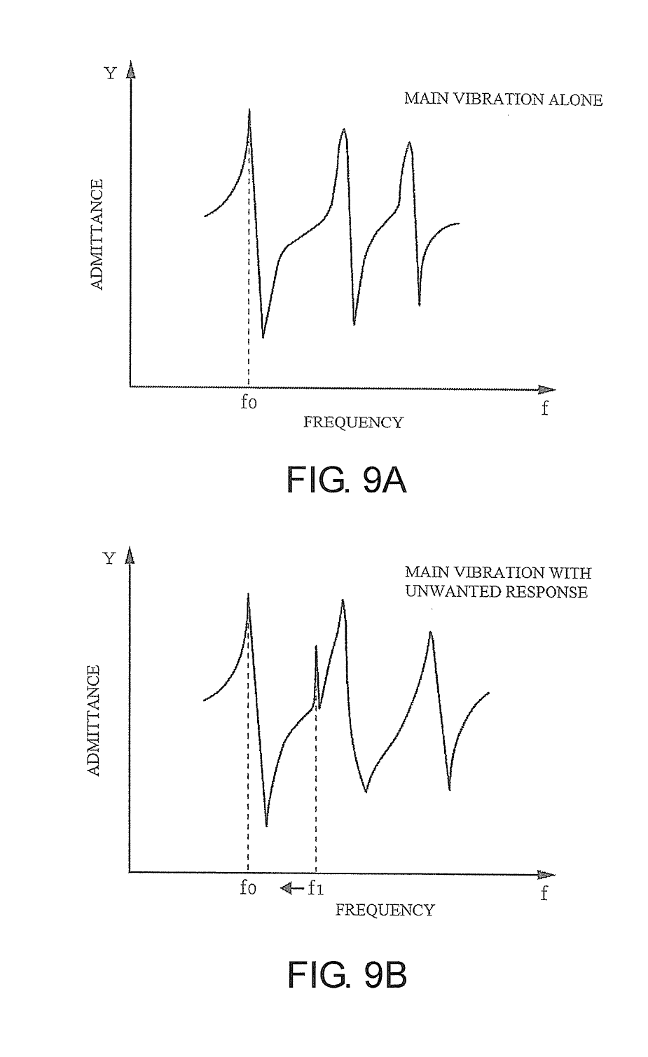

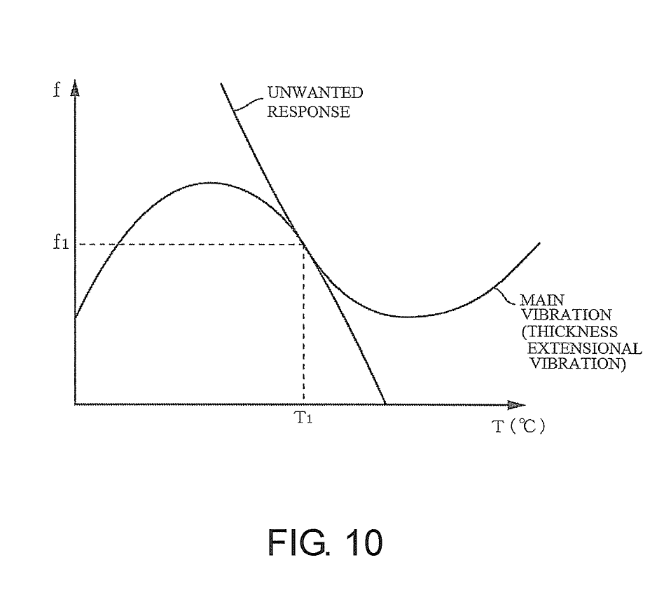

Considering only the main vibration (the thickness-shear vibration), the vibration of the piezoelectric resonator is represented by the curved line as illustrated in FIG. 9A in a relationship between oscillation frequency and admittance. However, in practice, the portion causing the unwanted response exists on the crystal unit as described above. For example, considering profile-shear vibration or flexure vibration as the unwanted response in addition to the main vibration, the relationship between oscillation frequency and admittance changes as illustrated in FIG. 9B. A value of admittance has a peak at a frequency f₁. In the piezoelectric resonator, vibration at the frequency f₁ is one of the unwanted responses. The frequency f₁ value can be obtained from a value f₁ of the frequency at an intersection point between the curved line and the straight line in a graph of a relationship between frequency and time passage as illustrated in FIG. 10. The curved line is illustrated based on a relationship between main vibration frequency and temperature. The straight line is illustrated based on a relationship between unwanted response frequency and temperature.

Here, a frequency of the fundamental wave of the piezoelectric resonator is assumed to be a peak frequency on the most left side of FIG. 9A. This frequency value is assumed to be fₒ. When the property of the unwanted response is changed, the straight line representing the unwanted response in FIG. 10 is shifted. Thus, the intersection point between the straight line and the curved line representing the main vibration is shifted. This changes the value of f₁. In the case where f₁ becomes equal to f₀ in FIG. 9B, the unwanted response is coupled to the main vibration. The phenomenon referred to as what is called frequency jump occurs, and shows an anomalous behavior as the entire piezoelectric resonator.

Generation of the unwanted response suppression portion, that is, the axis inverting portion by the present invention has a suppressive action on attenuation of the gain due to the unwanted response and the unwanted response itself. For example, the above-described embodiment shows suppressive effects on Frequency dips and Activity dips in the crystal unit. Further, generation of the unwanted response suppression portion is effective as a method for suppressing the above-described frequency jump. This shows an advantageous effect as a method for suppressing the negative effect due to the unwanted response in the piezoelectric resonator.

The present invention is applicable to a piezoelectric body such as ceramic or similar material in addition to a crystal element. The main vibration is not limited to thickness-shear vibration, and may be thickness extensional vibration, thickness-twisting vibration, or similar vibration. The unwanted response as a suppressing target of the present invention is not limited to profile-shear vibration or flexure vibration, and may include vibration caused by inharmonic overtone or similar vibration. The shape of the piezoelectric piece is not limited to a rectangular shape, and may be a circular shape or similar shape. In the case where the crystal element is used as the piezoelectric piece, the crystal element is not limited to an AT-cut crystal element, and may be a BT-cut crystal element or similar crystal element.

### Working Examples

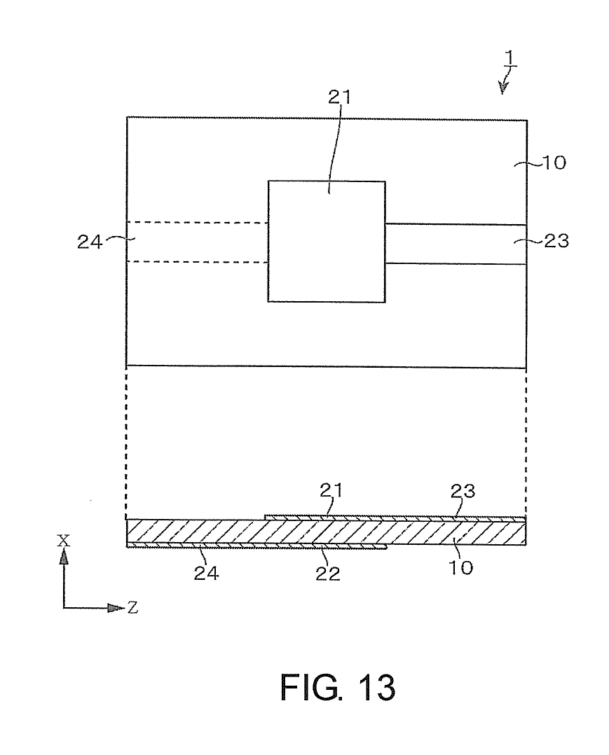

As a working example, regarding the crystal unit 1 according to the first embodiment, a temperature characteristic of the oscillation frequency is measured. A conventional crystal unit illustrated in FIG. 13 as a comparative example has a configuration where the unwanted response suppression portion 25 is removed from the crystal unit 1 according to the first embodiment. Regarding the conventional crystal unit, a temperature characteristic of the oscillation frequency is measured as a comparative example.

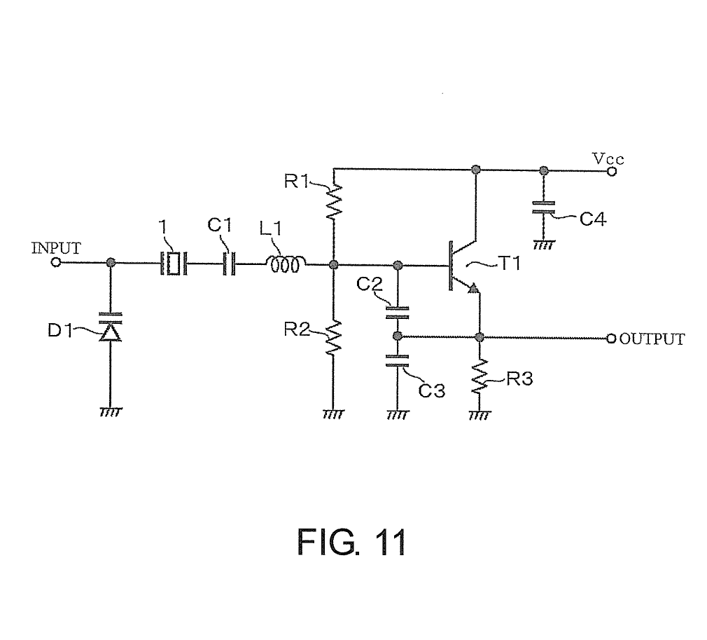

The crystal unit used for measurement employed an AT-cut crystal element that oscillates in a fundamental wave mode. The oscillation frequency of the main vibration was fₒ=38.4 MHz. The crystal oscillator of the working example and the crystal oscillator of the comparative example were each used as the crystal unit 1 in a crystal oscillator circuit illustrated in FIG. 11. Respective oscillation frequencies were measured and respective temperature characteristics of deviation Δf between fₒ and the measured oscillation frequency were obtained. In FIG. 11, condensers C1 to C4, resistors R1 to R3, an inductor L1, a transistor T1, and a diode D1 are illustrated.

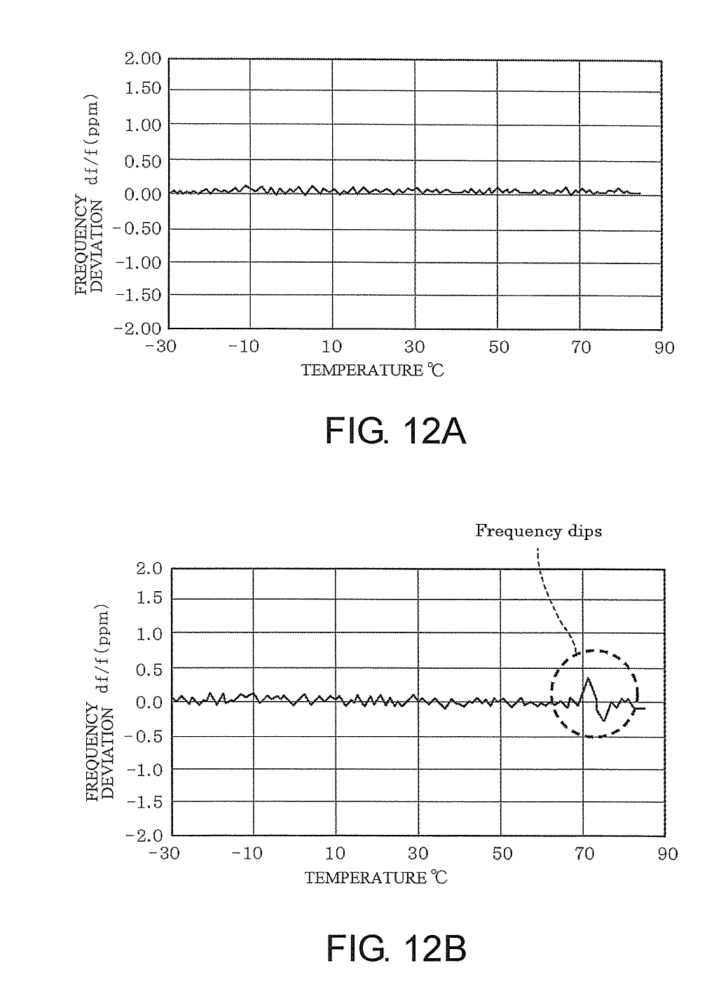

As a result, the obtained frequency characteristics are illustrated in FIGS. 12A and 12B. The graph of FIG. 12A shows the frequency characteristic of the working example. The graph of FIG. 12B shows the frequency characteristic of the comparative example. In FIGS. 12A and 12B, the horizontal axis indicates temperature (° C.) and the vertical axis indicates frequency deviation, that is, Δf/f₀ (ppm).

According to the graph of FIG. 12A, variation in oscillation frequency in association with the temperature change, what is called Frequency dips are not observed in the working example. On the other hand, in the graph of FIG. 12B, Frequency dips are observed around 70° C. in the comparative example.

Therefore, in this working example, it is estimated that forming the unwanted response suppression portion 25 in the crystal unit 1 suppresses the occurrence of the Frequency dips.

Also in the modification of the crystal unit 1 of the first embodiment, a similar result was obtained. Therefore, even the unwanted response suppression portion 25 formed directly below the excitation electrode 21 is considered to provide a similar effect of unwanted response suppression to the effect of the unwanted response suppression portion 25 formed outside the range of the excitation electrode 21.

What is claimed is:

1. A piezoelectric resonator, comprising:
a plate-shaped crystal element;
excitation electrodes disposed on both surfaces of the crystal element; and
an unwanted response suppression portion formed by inverting a crystallographic axis of the crystal element to suppress an unwanted response that oscillates at a different frequency from a frequency of a main vibration of the crystal element.

2. The piezoelectric resonator according to claim 1, wherein
the unwanted response suppression portion is formed by inverting an X-axis, the X-axis being the crystallographic axis of the crystal element.

3. The piezoelectric resonator according to claim 1, wherein
a plurality of the unwanted response suppression portions are disposed symmetrically to the center of the excitation electrode.

4. The piezoelectric resonator according to claim 3, wherein
the excitation electrode is formed in a quadrangular shape, the quadrangular shape being one of a rectangular shape and a square shape where lengths of four sides are equal to one another,
the unwanted response suppression portions include:
a first unwanted response suppression portion and a second unwanted response suppression portion disposed on one diagonal line of the quadrangular shape that is an outline of the excitation electrode, the first and second unwanted response suppression portions being symmetrical to each other with respect to a center of gravity of the quadrangular shape; and
a third unwanted response suppression portion and a fourth unwanted response suppression portion disposed on another diagonal line of the quadrangular shape, the third and fourth unwanted response suppression portions being symmetrical to each other with respect to the center of gravity of the quadrangular shape.

5. The piezoelectric resonator according to claim 1, wherein
the unwanted response suppression portion is formed in a position outside of projection regions of the excitation electrode and an extraction electrode.

6. The piezoelectric resonator according to claim 1, wherein
the unwanted response suppression portion is formed by bringing a needle portion into contact with a crystal element and locally heating the crystal element via the needle portion.

7. The piezoelectric resonator according to claim 1, wherein
the unwanted response suppression portion is disposed at one of a position directly below the excitation electrode and a position directly below an extraction electrode connected to the excitation electrode.

8. The piezoelectric resonator according to claim 1, wherein
the crystal element includes a first region where the crystallographic axis is not inverted and a second region where the crystallographic axis is inverted,
the first region includes the excitation electrodes and the unwanted response suppression portion, and
the second region includes other excitation electrodes different from the excitation electrodes, the other excitation electrodes being disposed on both surfaces of the crystal element.

9. The piezoelectric resonator according to claim 8, wherein
the excitation electrode disposed on both surfaces of the second region and the excitation electrode disposed on both surfaces of a region other than the second region are configured to operate independently from each other.

10. The piezoelectric resonator according to claim 1, wherein
the main vibration is thickness-shear vibration, and the unwanted response is one of profile-shear vibration and flexure vibration.

11. An etching amount detecting device, comprising:
the piezoelectric resonator according to claim 1, the piezoelectric resonator being immersed in an etchant in a state where a process target body to be etched is immersed in the same etchant; and
a frequency measuring unit configured to measure an oscillation frequency of the piezoelectric resonator for estimating an etching amount of the process target body.

12. An oscillator, comprising:
the piezoelectric resonator according to claim 8;
a main oscillation circuit connected to the excitation electrode in the first region;
an auxiliary oscillation circuit connected to the excitation electrode in the second region; and
a circuit unit configured to obtain a temperature compensation voltage based on an oscillation frequency of the auxiliary oscillation circuit, the temperature compensation voltage being to be added to a set voltage of a control voltage of the main oscillation circuit.
